(19) United States
(12) Patent Application Publication
(10) Pub. No.: US 2012/0074378 A1
(43) Pub. Date: Mar. 29, 2012

(54) MEMORY ELEMENT HAVING ELASTICALLY DEFORMABLE ACTIVE REGION

(76) Inventors: Wei Wu, Palo Alto, CA (US); Jianhua Yang, Palo Alto, CA (US); Zhiyong Li, Redwood City, CA (US); Shih-Yuan Wang, Palo Alto, CA (US); Dmitri Strukov, Mountain View, CA (US); Alexandre Bratkovski, Mountain View, CA (US)

(21) Appl. No.: 12/889,389

(22) Filed: Sep. 23, 2010

(51) Int. Cl. H01L 45/00; H01L 25/03

(52) U.S. Cl. 257/5; 257/1; 257/2; 257/E45.001; 257/E25.002

(57) ABSTRACT

A memory element is provided that includes a first electrode, a second electrode, and an active region disposed between the first electrode and the second electrode, wherein at least a portion of the active region comprises an elastically deformable material, and wherein deformation of the elastically deformable material causes said memory element to change from a lower conductive state to a higher conductive state. A multilayer structure also is provided that includes a base and a multilayer circuit disposed above the base, where the multilayer circuit includes at least of the memory elements including the elastically deformable material.

### STATEMENT OF GOVERNMENT INTEREST

The inventions disclosed herein have been made with U.S. Government support under Contract Number HR0011-09-3-0001 awarded by the Defense Advanced Research Projects Agency (DARPA). The U.S. Government has certain rights in these inventions.

### BACKGROUND

Three-dimensional (3D) circuits containing stacked, multiple layers of interconnected circuitry provide potential solutions for increasing the performance and planar density of integrated circuits. An example of such a 3D circuit is a memory circuit that is comprised of multiple layers of interconnected memory elements, each layer being an interconnected two-dimensional array (2D) of the memory elements. A memory element that can be switched between conductivity states through deformation of the active region would be beneficial. A memory circuit having a multilayer architecture of memory elements that are switched between conductivity states through deformation of the active region also would be beneficial.

### BRIEF DESCRIPTION OF THE DRAWINGS

The accompanying drawings illustrate various embodiments of the principles described herein and are a part of the specification. The illustrated embodiments are merely examples and do not limit the scope of the claims.

FIG. 1 illustrates a cross-sectional view of an example memory element.

FIG. 2 illustrates an example memory element according to the principles described herein.

FIG. 3 illustrates another example memory element according to the principles described herein.

FIG. 4 illustrates an example multilayer structure that includes memory elements.

FIG. 5A illustrates an example multilayer structure that includes a crossbar array of memory elements.

FIG. 5B illustrates a perspective view of the example crossbar array of FIG. 5A.

FIG. 5C illustrates a top view of the example crossbar array of FIG. 5A.

Throughout the drawings, identical reference numbers designate similar, but not necessarily identical, elements.

### DETAILED DESCRIPTION

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an embodiment,” “an example” or similar language means that a particular feature, structure, or characteristic described in connection with the embodiment or example is included in at least that one embodiment or example, but not necessarily in other embodiments or examples. The various instances of the phrases “in one embodiment,” “in one example,” or similar phrases in various places in the specification are not necessarily all referring to the same embodiment or example.

A “computer” is any machine, device, or apparatus that processes data according to computer-readable instructions that are stored on a computer-readable medium either temporarily or permanently. A “software application” (also referred to as software, an application, computer software, a computer application, a program, and a computer program) is a set of instructions that a computer can interpret and execute to perform one or more specific tasks. A “data file” is a block of information that durably stores data for use by a software application.

The term “computer-readable medium” refers to any medium capable storing information that is readable by a machine (e.g., a computer). Storage devices suitable for tangibly embodying these instructions and data include, but are not limited to, all forms of non-volatile computer-readable memory, including, for example, semiconductor memory devices, such as EPROM, EEPROM, and Flash memory devices, magnetic disks such as internal hard disks and removable hard disks, magneto-optical disks, DVD-ROM/RAM, and CD-ROM/RAM.

As used herein, the term “includes” means includes but not limited to, the term “including” means including but not limited to. The term “based on” means based at least in part on.

Provided herein are novel memory elements that can be switched between lower conductivity and higher conductivity states through elastic deformation of the active region of the memory elements. For example, the active region can include a material that is configured to behave elastically under deformation. In one example, the active region of the memory element is configured to deform to a deformed state, or relax from a deformed state, on application of a voltage across the electrodes of the memory element, to cause the memory element to switch between two different conductive states (a lower conductivity and a higher conductivity state). In another example, the memory element includes an actuator that can cause deformation of the active region of the memory element on application of a voltage across the electrodes of the memory element. In this example, the actuator is configured to cause the active region of the memory element to deform, or relax from a deformed state, on application of a voltage across the electrodes of the memory element, to cause the memory element to switch between two different conductive states (a lower conductivity and a higher conductivity state).

Also provided herein are multilayer structures that include multiple layers of interconnected circuitry of any of the memory elements described herein. A non-limiting example of such a multilayer structure is a memory circuit that is comprised of multiple layers of interconnected memory elements, each layer of the multilayer structure being an interconnected two-dimensional array (2D) of any of the memory elements described herein.

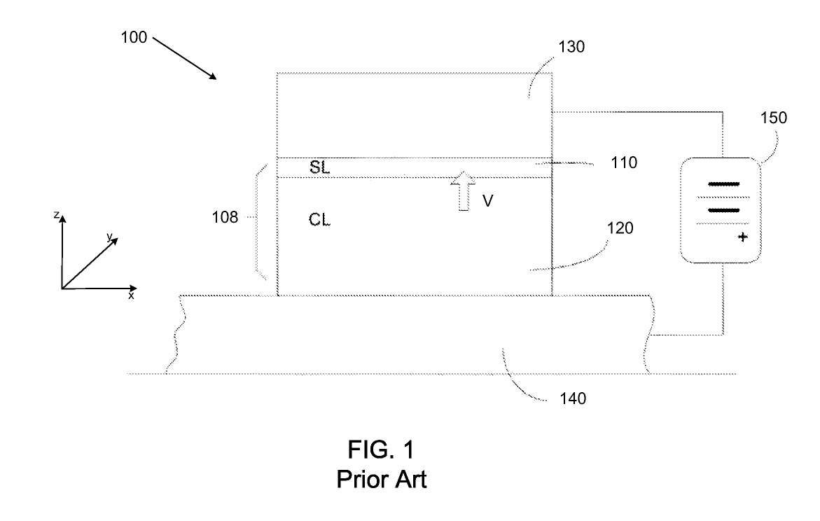

The structure and operation of an example is described in connection with FIG. 1. The memory element 100 includes electrodes 130, 140 and an active region 108. In the example of FIG. 1, the active region 108 of the memory element includes a switching layer (“SL”) 110 and a conductive layer (“CL”) 120. The switching layer 110 is formed of a switching material that is electronically insulating, semiconducting, or a weak ionic conductor. Examples of a switching material include a carbonate of silicon (including SiCO₄), an oxide of titanium (including TiO₂), a nitride of aluminum (including AlN), an oxide of silicon (including SiO₂), an oxide of hafnium, and an oxide of zirconium. The conductive layer 120 is formed of a dopant source material that serves as the source of doping species for the switching material. That is, the dopant source material includes a relatively high concentration of dopants of the type that can be transported by the switching material used. Examples of dopant source material include titanium sulphide, titanium phosphide, TiO₂₋ₓ (0<x<1), AlN_{1-w} (0<w<0.2), a plenary system (e.g., SrTiO₁—_{y} (0<y<0.2)), or a quaternary system. The type of dopant (depicted as a “V” in FIG. 1) depends on the type of dopant source material and switching material used. For example, in a system where the dopant source material AlN_{1-w} is used with switching material AlN, the dopant is nitrogen vacancies. As another example, where the dopant source material TiO₂₋ₓ is used with switching material TiO₂, the dopant is oxygen vacancies. The electrodes can be made of platinum, aluminum, copper, gold, or titanium, or any combination thereof, between about 7 nm and about 100 nm thick, or thicker. In an example, the electrode can be a copper/tantalum nitride/platinum system, where the copper is a very good conductor, and the tantalum nitride acts as a diffusion barrier between the copper and the platinum.

In operation, the conductive layer 120 serves as a reservoir of dopants that can drift into the switching material in the switching layer 110 during switching. FIG. 1 shows a voltage source 150 that can be used to apply an external DC voltage to the memory element. The memory element is switched between an ON state (higher conductivity state) and an OFF state (lower conductivity state) when a higher external DC voltage from a voltage source 150 is applied across the electrodes 130 and 140 to cause dopants to migrate from the conductive layer into the switching layer (ON state), or migrate from the switching layer into the conductive layer (OFF state). The state of the memory element is read when a lower external DC voltage from a voltage source is applied across the electrodes 130 and 140.

By contrast, the novel memory elements described herein are switched between conductivity states (i.e., between a lower conductivity state and high conductivity states) through a physical deformation of the active regions. The active region material is an elastically deformable material. Since the switching is based on the physical deformation of the active region material, the active region can be comprised of a single type of material in one example. In another example, the active region can be comprised of more than one type of material. In another example, the active region can be comprised of two or more layers of different materials. In the various examples described herein, the active region includes a material that is configured to behave elastically under deformation. That is, the active region material can be caused to recover substantially its original physical morphology after it is deformed.

In operation, with the application of a sufficiently high bias voltage (a “write” voltage) across the electrodes, an electrostatic force develops between the electrodes that causes the electrodes to be attracted to each other. The active region is configured to be deformable so that it deforms elastically under the force from the attraction of the electrodes. For example, the active region material can be selected as a deformable material having an elastic response (deformation and recovery) on the order of nanoseconds. The conductivity state of the active region of the memory element when the active region is in the recovered (i.e., undeformed) state is different from the conductivity state of the active region of the memory element when the active region is in the deformed state. In one example, the active region of the memory element is of a higher conductivity state when it is deformed and of a lower conductivity state when it is recovered (i.e., undeformed). In this example, when the active region of the memory element is deformed, a tunneling current can develop and as a result the material can be more conductive (i.e., change to a higher conductivity state). The magnitude of the tunneling current can change exponentially with a change in thickness. For example, a change in thickness of the active region by about 1 angstrom can cause an order of magnitude change in the tunneling current. In one example where the memory element is volatile, the active region relaxes back to the recovered (i.e., undeformed) state when the application of the “write” voltage is discontinued. In another example where the memory element is nonvolatile, the active region retains the deformed state even after the “write” voltage is discontinued, and relaxes to the recovered (i.e., undeformed) state only application of an “erase voltage setup.” A “read” voltage, that is of much lower magnitude than the “write” voltage, can be applied to the memory element to “read” the state of the memory element. The “read” voltage is generally one or two orders of magnitude smaller than the “write” voltage. Since the “read” voltage is of much lower magnitude than the “write” voltage, it applies a much lower bias across the electrodes, resulting in a much smaller deformation of the active region that does not change the “write” state of the memory element. In some examples, the much lower bias across the electrodes from the “read” voltage results in a minimal deformation of the active region.

In one example, the active region material is comprised of a polymer material that includes microparticles or nanoparticles. In this example, the polymer material can be an elastomer material or other matrix material. The elastomer material can be based on polydimethylsiloxane (PDMS). The microparticles or nanoparticles can be metal particles. The microparticles or nanoparticles can be configured and distributed in the polymer material such that the microparticles or nanoparticles exhibit some attraction to each other when the active region is deformed (squeezed), bringing the microparticles or nanoparticles closer together. In deformation, the microparticles or nanoparticles (such as but not limited to metal particles) can be brought closer together resulting in a greater tunneling or hopping current. In this example, the deformed state of the active region is the higher conductivity state and the recovered state is the lower conductivity state. The active region material can be configured such that the memory element is nonvolatile, i.e., even after the “write” voltage is discontinued, the memory element retains the state it was set to with application of the “write” voltage. In this example, the active region material can be configured such that an attraction between the microparticles or nanoparticles can maintain the active region in the deformed state in the absence of application of an “erase voltage setup” that causes the active region to relax to the recovered state. In another example, the active region material can be configured such that the memory element is volatile, where the memory element reverts from the state it was set to with application of the “write” voltage, once the “write” voltage is discontinued.

In another example, the active region material is comprised of a polymer material that includes memristor material. In this example, the polymer material can be an elastomer material or other matrix material. The elastomer material can be based on polydimethylsiloxane (PDMS). The memristor material can be in the form of microparticles, nanoparticles, or thin films. In an example, the memristor material is based on layers of a switching material and a conductive material such as described in connection with FIG. 1. In an example, the switching material can be TiO₂ and the conductive material can be TiO₂₋ₓ. For example, the microparticles and nanoparticles can be formed as a switching material core (such as TiO₂) and a conductive material shell (TiO₂₋ₓ) layer. The microparticles or nanoparticles can be configured and distributed in the polymer material such that, when the active region is deformed bringing the distributed memristor material closer together, a memristive path is established between the memristor material that behaves like memristors in series. That is, the memristive path established between the memristor material can allow current to flow, which provides a higher conductivity state. In this example, the deformed state of the active region is the higher conductivity state and the recovered state is the lower conductivity state. The active region material can be configured such that the memory element is nonvolatile, i.e., even after the “write” voltage is discontinued, the memory element retains the state it was set to with application of the “write” voltage. In another example, the active region material can be configured such that the memory element is volatile, where the memory element reverts from the state it was set to with application of the “write” voltage once the “write” voltage is discontinued.

In yet another example, the active region material is comprised of a porous memristor material that behaves elastically under deformation. For example, the porous memristor material can be a porous metal, or porous TiO₂₋ₓ The TiO₂₋ₓ can be treated using etching to make it porous. The active region material can be configured such that the memory element is nonvolatile, i.e., even after the “write” voltage is discontinued, the memory element retains the state it was set to with application of the “write” voltage. In another example, the active region material can be configured such that the memory element is volatile, where the memory element reverts from the state it was set to with application of the “write” voltage once the “write” voltage is discontinued.

In yet another example, the active region material is comprised of a multi-layer thin film super-lattice. For example, the active region material can include a multilayer sequence of thin film semiconductor and elastic layers. As a non-limiting example, the active region material can comprise the following sequence of materials: a semiconductor layer/an elastic layer/a semiconductor layer/an elastic layer, and so forth. This multi-layer thin film super-lattice structure possesses a sub-conduction band or sub-valence band electronic structure. The deformation of the elastic layers can cause the electronic sub-bands either to aligned (to provide the higher conduction state) or to mis-aligned (to provide the lower conduction state).

In examples described herein, the active region can be made to have a thickness on the order of nanometers to allow easier switching between the deformation states (i.e., between a recovered state and a deformed state). In these examples, the active region material can range from about 10 nm to about less than about 100 nm in thickness (t) to allow easier switching between deformation states. A lower switching (“write”) voltage can be used to switch a memory element having a thinner active region. For example, a “write” of about 4 V can be used to switch such a memory element as compared to a switching voltage of about 10 V or higher that may be used in other examples.

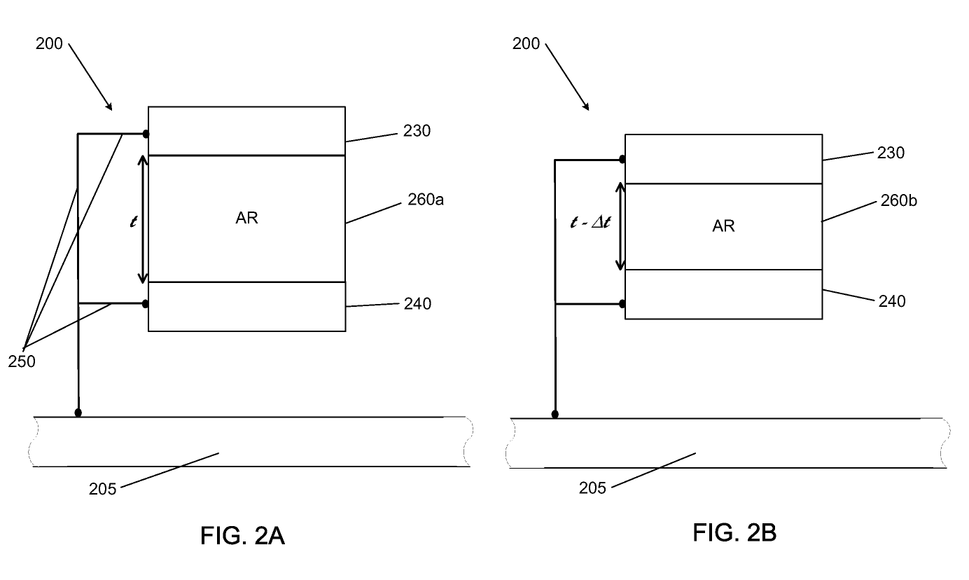

The active region of the memory element can be configured to deform, or relax from a deformed state, on application of a voltage across the electrodes of the memory element, to cause the memory element to switch between two different conductive states (a lower conductivity and a higher conductivity state). FIG. 2A illustrates an example of a novel memory element according to this principle. The memory element includes electrodes 230, 240, and an active region 260a disposed between the electrodes. The electrodes 230, 240 are connected to a base 205 through conductive lines 250. The electrodes 230, 240 range from about 10 nm to about 300 nm in thickness. The active region 260a can range from about 10 nm to about 1 μm in thickness (t). FIG. 2A illustrates the memory element in a first state with the active region 260a in a recovered state of thickness t. FIG. 2B illustrates the memory element in a second state with the active region 260b in a deformed state with reduced thickness t−Δt. In one example, the first state is a low conductivity state and the second state is a high conductivity state. In another example, the second state is a low conductivity state and the first state is a high conductivity state. The active region 260a or 260b can be comprised of any of the example active region materials described herein.

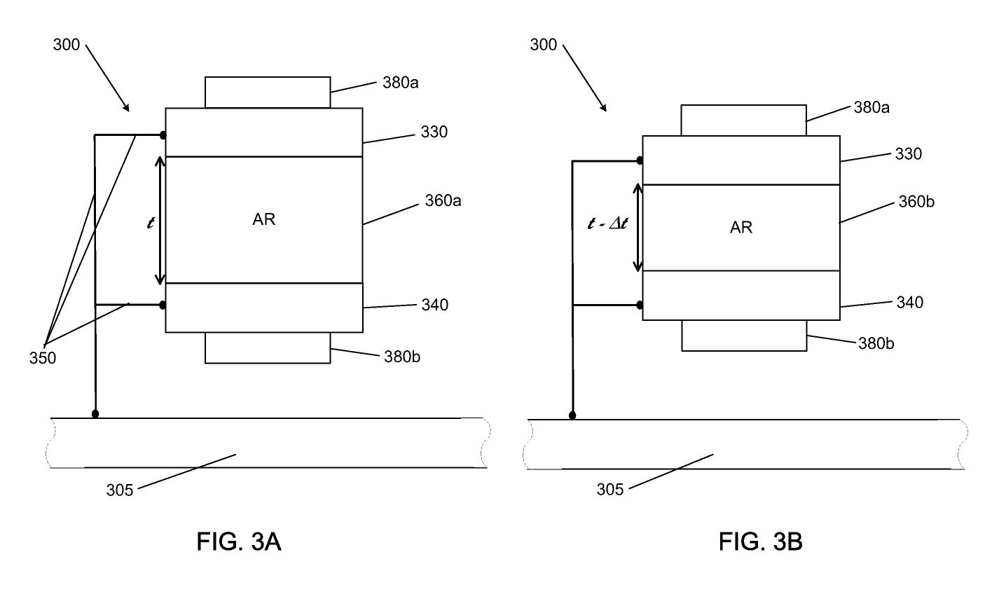

The memory element can include an actuator that causes deformation of the active region of the memory element on application of a voltage across the electrodes of the memory element. In this example, the actuator is configured to cause the active region of the memory element to deform, or relax from a deformed state, on application of a voltage across the electrodes of the memory element, to cause the memory element to switch between two different conductive states (a lower conductivity and a higher conductivity state). FIG. 3A illustrates an example of a novel memory element according to this principle. The memory element includes electrodes 330, 340, and an active region 360a disposed between the electrodes. Actuator prongs 380b and 380b disposed near the electrodes 330, 340, can be used to cause deformation of the active region of the memory element on application of a voltage across the electrodes 330, 340 of the memory element. The actuator prongs can be comprised of a piezoelectric material. In an example, the actuator prongs are portions of a microelectromechanical (MEMS) device. The electrodes 330, 340 are connected to a base 305 through conductive lines 350. The electrodes 330, 340 range from about 10 nm to about 500 nm in thickness. The active region 360a can range from about 10 nm to about 1 μm in thickness (t). FIG. 3A illustrates the memory element in a first state with the active region 360a in a recovered state of thickness t. FIG. 3B illustrates the memory element in a second state with the active region 360b in a deformed state with reduced thickness t−Δt. In one example, the first state is a low conductivity state and the second state is a high conductivity state. In another example, the second state is a low conductivity state and the first state is a high conductivity state. The active region 360a or 360b can be comprised of any of the example active region materials described herein.

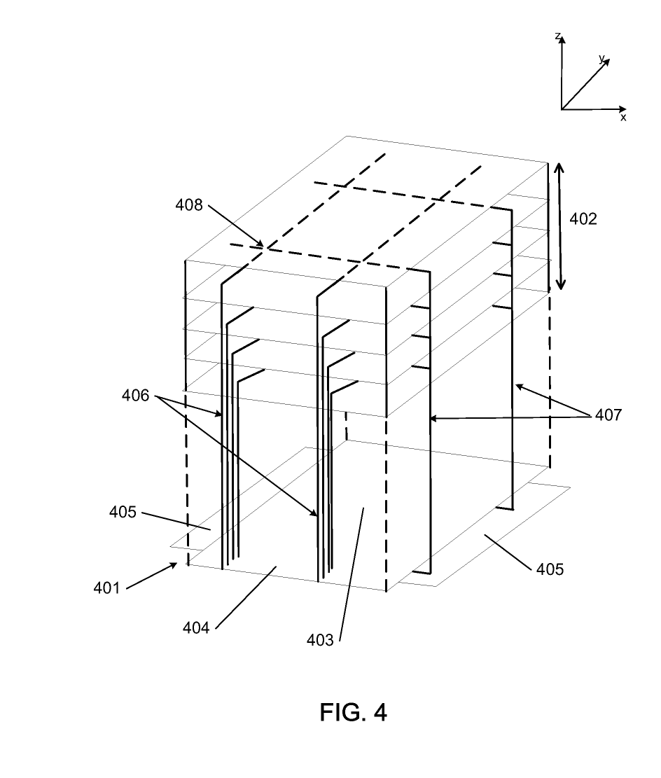

FIG. 4 illustrates an example of a multilayer structure that includes an interconnected array of the memory elements described herein. The multilayer structure is configured as a base on which a memory circuit 402 is laminated, with conductive lines 406 and 407 leading from the base to each layer of the multilayer structure. The example of FIG. 4 shows a multilayer structure having edge-disposed conductive lines 406 and 407. Memory elements 408 are positioned in each 2D array on each layer at the intersection of conductive lines 406 and 407. Each memory element 408 in the multilayer structure of FIG. 4 can be the memory element described herein in connection with FIG. 2 or the memory element described herein in connection with FIG. 3. In another example, the multilayer structure of FIG. 4 includes some combination of the memory element described herein in connection with FIG. 2 and the memory element described herein in connection with FIG. 3. The base can include a semiconductor substrate 401, a wiring area 403 (such as formed from CMOS circuitry), and contact areas 404 and 405 for the conductive lines. Conductive lines 406 and 407 connect each layer of interconnected memory cells to the wiring area 403 formed on the semiconductor substrate 401. Contact areas 404 and 405 are provided along four edges of the wiring area 403. The memory circuit 402 is illustrated as having four layers of 2D arrays of the interconnected memory elements. However, the memory circuit can include more or fewer than four layers of 2D arrays. The wiring area 403 is provided in the semiconductor substrate 401 below the memory circuit 402. In the wiring area 403, a global bus or the like is used for providing instructions for writing (i.e., putting memory elements to ON or OFF states) or reading from the circuit 402 with outside sources. That is, the external voltage is applied to a memory element using conductive lines 406 and 407. In some examples, wiring area 403 includes a column control circuit including a column switch and/or a row control circuit including a row decoder. In one example, the OFF state is the higher conductivity and the ON state is the lower conductivity state. In another example, the ON state is the higher conductivity and the OFF state is the lower conductivity state. In an example where the multilayer structure of FIG. 4 includes at least one of the memory elements described herein in connection with FIG. 3, conductive lines leading from the base can be used to actuate the actuator to result in deformation or recovery of the active region as described herein.

FIG. 4 shows one multilayer structure obtained by laminating a plurality of interconnected memory cells in a direction perpendicular to the semiconductor substrate 401 (z direction shown in FIG. 4). However, an actual structure can include a plurality of multilayer structures arranged in a matrix form in the longitudinal x-direction and/or in the longitudinal y-direction (shown in FIG. 4).

In the example of FIG. 4, conductive lines 406 can be driven independently using the external applied voltage in each layer and conductive lines 407 in all layers are illustrated as connected in common. However, it is also contemplated that conductive lines 407 may be driven independently in each layer using the external applied voltage. Alternatively, conductive lines 406 may be connected in common and conductive lines 407 may be driven independently using the external applied voltage. Further, at least one of conductive lines 406 and conductive lines 407 may be shared by upper and lower layers of the multilayer structure. The CMOS circuitry can be configured to selectively address (including applying external voltages to) ones of the memory elements using the conductive lines 406, 407. In an example where the multilayer structure of FIG. 4 includes at least one of the memory elements described herein in connection with FIG. 3, conductive lines leading from the base to serve to actuate the actuator to result in deformation or recovery of the active region as described herein. In an example where the multilayer structure of FIG. 4 includes at least one of the memory elements described herein in connection with FIG. 3, the CMOS circuitry can be used to actuate the actuator to result in deformation or recovery of the active region as described herein using conductive lines leading from the base.

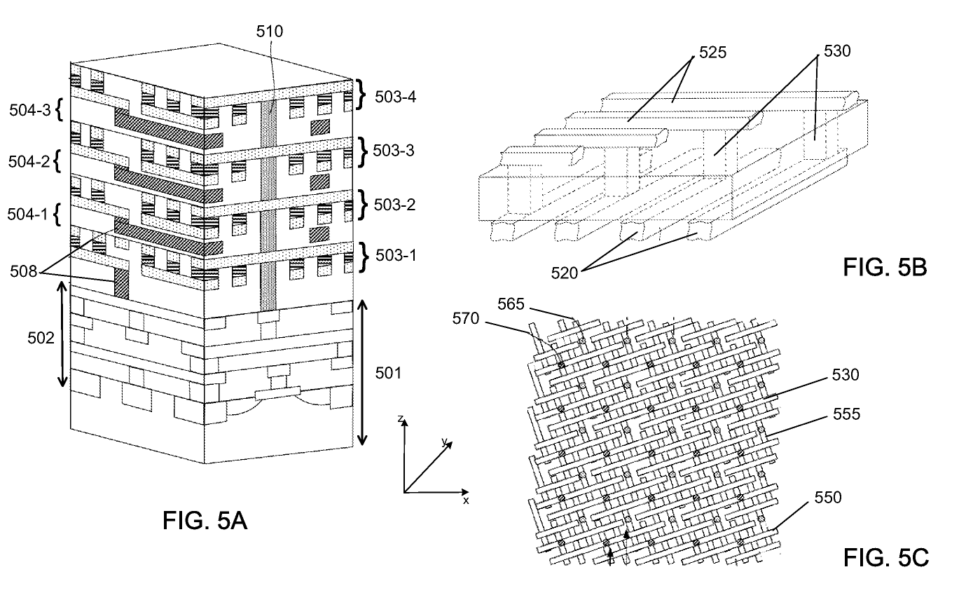

FIG. 5A illustrate another example of a multilayer structure that includes an interconnected array of the memory elements described herein. The multilayer structure 500 includes a base 501 and a multilayer circuit disposed above the base. The base includes a CMOS layer 502. The multilayer circuit includes layers of interconnected memory elements, each layer being formed as a 2D crossbar array 503-i (i=1, . . . , 4). FIG. 5B illustrates a portion of a 2D crossbar array composed of a lower layer of approximately parallel nanowires 520 that are overlain by an upper layer of approximately parallel nanowires 525. The nanowires of the upper layer 525 are roughly perpendicular, in orientation, to the nanowires of the lower layer 520, although the orientation angle between the layers may vary. The two layers of nanowires form a lattice, or crossbar, in which each nanowire of the upper layer 525 overlies all of the nanowires of the lower layer 520. In this example, the memory elements 530 are formed between the crossing nanowires at these intersections. Each nanowire 525 in the upper layer is connected to every nanowire 520 in the lower layer through a memory element and vice versa. FIG. 5C illustrates a top view of the crossbar array, showing a set of upper crossbar wires (550), a set of lower crossbar wires (555), and a number of programmable memory elements (560) interposed at the intersection between the upper crossbar wires (550) and the lower crossbar wires (555). Each memory element 530 in the multilayer structure of FIGS. 5A-5C can be the memory element described herein in connection with FIG. 2 or the memory element described herein in connection with FIG. 3. In another example, the multilayer structure of FIGS. 5A-5C includes some combination of the memory element described herein in connection with FIG. 2 and the memory element described herein in connection with FIG. 3. In an example where the multilayer structure of FIGS. 5A-5C include at least one of the memory elements described herein in connection with FIG. 3, conductive lines leading from the base can be used to actuate the actuator to result in deformation or recovery of the active region as described herein.

Different types of conductive lines form the conductive path that leads from the base to the memory elements of the crossbar arrays of the example multilayer structure of FIG. 5A. One type of conductive line is wiring layers 504-i (i=1, . . . , 3) that are interposed between successive crossbar arrays 503-i (see FIG. 5A). Another type of conductive line that form the conductive path that connects the crossbar array to the base is two groups of vias 508, 510 (see FIG. 5A). A first group of vias 508 connects to the lower crossbar lines (nanowires 520) and a second group of vias 510 connects to the upper crossbar lines (nanowires 525). The second vias 510 pass through all the crossbar arrays 503-i and wiring layers 504-i as a vertical column. In contrast, the locations of the first vias 508 are shifted in each successive wiring layer 504-i. FIG. 5C also shows a top view of the first vias 565 and second vias 570 in the 2D crossbar array. Portions of the nanowires 520, 525 between the memory elements also serve as conductive lines. The use of the conductive lines, including the wiring layers 504-i, first vias 508, second vias 510, lower crossbar lines (nanowires 520) and upper crossbar lines (nanowires 525), to uniquely address (including applying voltages to read data and/or to write data (i.e., set to an ON state or OFF state)) to the memory elements in the multilayer structure of FIG. 5A-C is described in greater detail in international application no. PCT/US2009/039666, filed Apr. 6, 2009, titled “Three-Dimensional Multilayer Circuit,” which is incorporated herein by reference in its entirety. In one example, the OFF state is the higher conductivity and the ON state is the lower conductivity state. In another example, the ON state is the higher conductivity and the OFF state is the lower conductivity state. The CMOS circuitry can be configured to selectively address (including applying external voltages to) ones of the memory elements using the conductive lines (including the wiring layers 504-i, first vias 508, second vias 510, lower crossbar lines (nanowires 520) and upper crossbar lines (nanowires 525)). In an example where the multilayer structure of FIGS. 5A-5C include at least one of the memory elements described herein in connection with FIG. 3, the CMOS circuitry can be used to actuate the actuator to result in deformation or recovery of the active region as described herein using conductive lines leading from the base.

Although individual nanowires (520, 525) in FIG. 5B are shown with rectangular cross sections, nanowires can also have square, circular, elliptical, or more complex cross sections. The nanowires may also have many different widths or diameters and aspect ratios or eccentricities. The crossbar lines may have one or more layers of sub-microscale wires, microscale wires, or wires with larger dimensions, in addition to nanowires.

The three dimensional multilayer structures described above could be used in a variety of applications. For example, the multilayer structures could be used as a very high density memory which replaces Dynamic Random Access Memory for computing applications; incorporated into a high density portable storage device that replaces flash memory and other removable storage devices for cell phones, cameras, net book and other portable applications; a very high density storage medium to replace magnetic hard disks and other forms of permanent or semi-permanent storage of digital data; and/or a very high density cache or other memory integrated on top of a computer processor chip to replace Static Random Access Memory. For example, the memory elements described herein can be used in applications using different types of memory, e.g., capacitor, variable capacitor, floating gate transistor, four transistor feedback loop circuit, or magnetic tunnel junction in commercialized DRAM, FeRAM, NOR flash, SRAM or MRAM, technologies, correspondingly. The read/write operations may not be the same for the different types of memories, but in general, e.g., read involves sensing either the charge of a particular memory element or passing current through the memory element.

In sum, the three dimensional multilayer structures described above provides memory circuits having a multilayer architecture of memory elements that present uniform electrical properties, including uniform internal voltages, regardless of position in the multilayer structure for a given external applied voltage. Memory elements that are accessed in the multilayer structure by conductive lines leading from the base with a higher total resistance are configured to have a higher overall resistance than memory elements that are accessed by conductive lines leading from the base with a lower total resistance. A memory element can be made to have a greater overall resistance by increasing the thickness of the switching layer, using a switching material of a higher resistivity, increasing the lateral dimensions of the switching layer, or some combination thereof.

The preceding description has been presented only to illustrate and describe embodiments and examples of the principles described. This description is not intended to be exhaustive or to limit these principles to any precise form disclosed. Many modifications and variations are possible in light of the above teaching.

What is claimed is:

1. A memory element comprising:
a first electrode;
a second electrode; and
an active region disposed between the first electrode and the second electrode, wherein at least a portion of the active region comprises an elastically deformable material, and wherein deformation of the elastically deformable material causes said memory element to change from a lower conductive state to a higher conductive state.

2. The memory element of claim 1, wherein a bias voltage applied across the first electrode and second electrode causes the first electrode and second electrode to deform the elastically deformable material.

3. The memory element of claim 1, further comprising an actuator associated with the first electrode and second electrode, wherein, when a bias voltage is applied across the first electrode and second electrode, the actuator causes the first electrode and second electrode to deform the elastically deformable material.

4. The memory element of claim 1, wherein the elastically deformable material is a porous memristor material.

5. The memory element of claim 1, wherein the elastically deformable material is a polymer comprising a memristor material.

6. The memory element of claim 5, wherein the polymer is a polydimethylsiloxane matrix.

7. The memory element of claim 1, wherein the elastic material is a polymer comprising metal microparticles or metal nanoparticles.

8. The memory element of claim 1, wherein the elastically deformable material is a multi-layer thin film super-lattice structure comprising at least one layer of a semiconductor material and at least one layer of an elastic material.

9. A multilayer structure comprising:
a base;
a multilayer circuit disposed above the base, wherein the multilayer circuit comprises at least one memory element of claim 1; and
conductive lines leading from the base to the at least one memory element.

10. The multilayer structure of claim 9, wherein the base comprises CMOS circuitry.

11. The memory element of claim 10, wherein a bias voltage applied across the first electrode and second electrode using the CMOS circuitry causes the first electrode and second electrode to deform the elastically deformable material.

11. The memory element of claim 10, further comprising an actuator associated with the first electrode and second electrode, wherein, when a bias voltage is applied across the first electrode and second electrode using the CMOS circuitry, the actuator causes the first electrode and second electrode to deform the elastically deformable material.

12. The multilayer structure of claim 9, further comprising conductive lines leading from the base to the actuator, wherein the CMOS circuitry is used to actuate the actuator.

13. The multilayer structure of claim 9, further comprising:
a via array comprising a set of first vias and a set of second vias; and
at least two crossbar arrays configured to overlie the base, wherein the at least two crossbar arrays form at least one intersections, wherein the at least one memory element are positioned at the at least one intersection, and
wherein the conductive lines leading from the base to the at least one memory element comprise at least one first via, at least one second via, and at least two crossbar lines of the at least two crossbar arrays.

13. The multilayer structure of claim 9, wherein the multilayer structures is used as a dynamic random access memory, a flash memory, memory for a cell phone, memory for a camera, memory for a net book computer, or a static random access memory.

14. The multilayer structure of claim 9, wherein the multilayer structure is a volatile memory or a nonvolatile memory.

15. A multilayer structure comprising:
a via array comprising a set of first vias and a set of second vias;
a CMOS layer to selectively address the set of first vias and the set of second vias;
at least two crossbar arrays configured to overlie the CMOS layer and communicate with at least one of the first vias and the second vias, each of the at least two crossbar arrays intersect at a plurality of intersections; and
memory elements configured to be interposed at the intersections, wherein each memory element comprises:
a first electrode;
a second electrode; and
an active region disposed between the first electrode and the second electrode, wherein at least a portion of the active region comprises an elastically deformable material, and wherein deformation of the elastically deformable material causes said memory element to change from a lower conductive state to a higher conductive state.

16. The memory element of claim 15, wherein a bias voltage applied across the first electrode and second electrode causes the first electrode and second electrode to deform the elastically deformable material.

17. The memory element of claim 15, further comprising an actuator associated with the first electrode and second electrode, wherein, when a bias voltage is applied across the first electrode and second electrode, the actuator causes the first electrode and second electrode to deform the elastically deformable material.

18. The multilayer structure of claim 17, further comprising conductive lines leading from the base to the actuator, wherein the CMOS circuitry is used to actuate the actuator.

19. The multilayer structure of claim 15, wherein the multilayer structures is used as a dynamic random access memory, a flash memory, memory for a cell phone, memory for a camera, memory for a net book computer, or a static random access memory.

20. The multilayer structure of claim 15, wherein the multilayer structure is a volatile memory or a nonvolatile memory.
